(19) United States
(12) Patent Application Publication
(10) Pub. No.: US 2010/0225343 A1
(43) Pub. Date: Sep. 9, 2010

(54) Probe card, semiconductor testing device including the same, and fuse checking method for probe card

(75) Inventor: Takayuki Kouno, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/656,726

(22) Filed: Feb. 16, 2010

(30) Foreign Application Priority Data
Mar. 6, 2009 (JP) 2009-053257

(51) Int. Cl. G01R 31/02; G01R 31/26

(52) U.S. Cl. 324/754; 324/765; 324/550

(57) ABSTRACT

A probe card according to an exemplary aspect of the present invention includes: a force terminal supplied with a first power supply voltage; a probe needle that supplies a voltage corresponding to the first power supply voltage to a semiconductor integrated circuit to be tested; a fuse connected in series on a first signal line which connects the force terminal and the probe needle; and a fuse check circuit that supplies a voltage different from the first power supply voltage supplied from the force terminal, to a first node located on a signal line between the probe needle and one end of the fuse. The circuit configuration enables checking of a connection state of a fuse prior to product inspection. This makes it possible to perform semiconductor testing with high reliability.

### INCORPORATION BY REFERENCE

This application is based upon and claims the benefit of priority from Japanese patent application No. 2009-053257, filed on Mar. 6, 2009, the disclosure of which is incorporated herein in its entirety by reference.

### BACKGROUND

1. Field of the Invention

The present invention relates to a probe card, a semiconductor testing device including the same, and a fuse checking method for a probe card.

2. Description of Related Art

In recent years, testing for electrical characteristics of a semiconductor integrated circuit formed on a wafer has been generally performed. Such testing is performed in such a manner that a test jig called a probe card is mounted in a semiconductor testing device. First, the semiconductor testing device causes a probe needle, which is provided on the probe card, to contact an electrode of the semiconductor integrated circuit. The semiconductor testing device then applies a test signal to the semiconductor integrated circuit. After that, the semiconductor testing device compares an output signal from the semiconductor integrated circuit with an expected value. Thus, the semiconductor testing device checks to see if there is a problem with the electrical characteristics of the semiconductor integrated circuit. In this case, it is necessary for the semiconductor testing device to supply a stable power supply voltage to the semiconductor integrated circuit. In a semiconductor testing device of the related art, however, there arises a problem that when a current having a value equal to or greater than a predetermined current value (i.e., overcurrent) flows to the probe needle, the probe needle is damaged (e.g., needle bum or needle melting). This causes a problem of deterioration in reliability of product inspection.

A countermeasure against this problem is disclosed in Japanese Unexamined Patent Application Publication No. 2002-124552. FIG. 3 shows a semiconductor testing device disclosed in Japanese Unexamined Patent Application Publication No. 2002-124552. The circuit shown in FIG. 3 includes relays 1, fuses 2, probe needles 3, units under test 4, a ground (ground voltage terminal) 5, and a measuring device 10. The measuring device 10 applies current to the units under test 4 through the relays 1 and the fuses 2. A description is herein given of a case where an overcurrent flows between the measuring device 10 and the units under test 4 in a state where the measuring device 10 and the fuses 2 are connected to each other. In this case, when the current flowing to the fuses 2 exceeds a predetermined current value, the fuses 2 are fused. Thus, no current flows between the measuring device 10 and the units under test 4. That is, no current flows to the probe needles 3 as well. For example, a configuration is made such that the fuses 2 are fused before the current flowing to the probe needles 3 reaches the current value at which the probe needles 3 are damaged. This prevents the probe needles 3 from being damaged due to an overcurrent, for example.

### SUMMARY

The present inventor has found a problem as described below. In the circuit shown in FIG. 3, each of the fuses 2 is connected in series between the measuring device 10 and each of the units under test 4. Thus, a power supply voltage supplied to each of the probe needles 3 is affected by a voltage drop due to a resistance component of each of the fuses 2. Accordingly, it is impossible for the circuit shown in FIG. 3 to supply the power supply voltage with high reliability from the measuring device 10 to the semiconductor integrated circuit. This may cause deterioration in reliability of product inspection.

As described above, the probe card according to the related art has a problem that product inspection cannot be performed with high reliability, under the effect of fuses for protection against an overcurrent or the like.

A first exemplary aspect of the present invention is a probe card including: a first power supply electrode (corresponding to a force terminal 105 according to a first exemplary embodiment of the present invention) that is supplied with a first power supply voltage; a probe needle that supplies a voltage corresponding to the first power supply voltage to a semiconductor integrated circuit to be tested; a first signal line that connects the first power supply electrode and the probe needle; a fuse that is connected in series on the first signal line; and a fuse check circuit that supplies a voltage different from the first power supply voltage, to a first node (corresponding to a node 119 according to the first exemplary embodiment of the present invention) which is located on the first signal line between the probe needle and one end of the fuse.

The above-mentioned circuit configuration enables checking of a connection state of the fuse prior to product inspection. Consequently, the product inspection can be performed with high reliability.

A second exemplary aspect of the present invention is a fuse checking method for a probe card, the probe card including: a first power supply electrode (corresponding to the force terminal 105 according to the first exemplary embodiment of the present invention) that is supplied with a first power supply voltage; a probe needle that supplies a voltage corresponding to the first power supply voltage to a semiconductor integrated circuit to be tested; a first signal line that connects the first power supply electrode and the probe needle; a fuse that is connected in series on the first signal line; and a fuse check circuit that supplies a voltage different from the first power supply voltage, to a first node (corresponding to the node 119 according to the first exemplary embodiment of the present invention) which is located on the first signal line between the probe needle and one end of the fuse, the fuse checking method including: applying the first power supply voltage from the first power supply electrode; supplying a voltage different from the first power supply voltage, to the first node by turning on a switch element provided in the fuse check circuit; and detecting a connected state of the fuse when a current corresponding to a potential difference between both terminals of the fuse flows to the first power supply electrode, and detecting a fused state of the fuse when the current corresponding to the potential difference between the both terminals of the fuse flows to the first power supply electrode. Note that a semiconductor testing device according to an exemplary aspect of the present invention has a function (not shown) for measuring a current value of the first power supply electrode.

The above-mentioned fuse checking method for a probe card enables checking of a connection state of a fuse prior to product inspection. Consequently, the product inspection can be performed with high reliability.

According to exemplary aspects of the present invention, it is possible to provide a probe card and a fuse checking method that are capable of performing product inspection with high reliability.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a diagram showing a probe card and a semiconductor testing device according to a first exemplary embodiment of the present invention;

FIG. 2 is a flowchart showing a fuse checking method for the probe card according to the first exemplary embodiment of the present invention;

FIG. 3 is a diagram showing a semiconductor testing device according to a related art;

FIG. 4 is a diagram showing a semiconductor testing device according to a related art; and

FIG. 5 is a diagram showing a semiconductor testing device according to a related art.

### DETAILED DESCRIPTION OF THE EXEMPLARY EMBODIMENTS

An exemplary embodiment of the present invention will be described in detail below with reference to the accompanying drawings. The same components are denoted by the same reference numerals throughout the drawings, and a redundant explanation thereof is omitted as appropriate for clarification of the explanation.

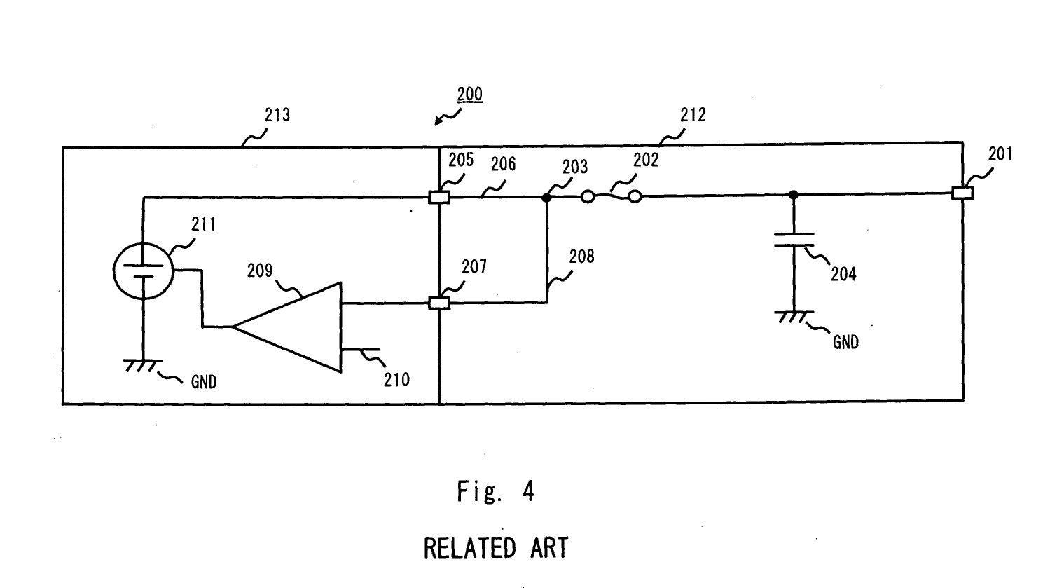

First, a more detailed description will be given of the related art to be compared with a semiconductor testing device according to the present invention. FIG. 4 shows a semiconductor testing device according to the related art. A circuit shown in FIG. 4 is a semiconductor testing device 200 which includes a probe card 212 and a semiconductor testing device body 213.

The configuration of the circuit shown in FIG. 4 will be first described. The semiconductor testing device body 213 includes an amplifier 209 and a power supply voltage source 211, and supplies a power supply voltage to a semiconductor integrated circuit. In the semiconductor testing device body 213, one input terminal of the amplifier 209 is connected to a reference voltage terminal 210. For convenience of description, a reference voltage supplied to the reference voltage terminal 210 is referred to as a reference voltage 210. The other input terminal of the amplifier 209 is connected to a sense terminal 207. For convenience of description, it is assumed that the sense terminal 207 is a terminal common to the probe card 212 and the semiconductor testing device body 213. Likewise, it is assumed that a force terminal 205 is a terminal common to the probe card 212 and the semiconductor testing device body 213. An output terminal of the amplifier 209 is connected to a control terminal of the power supply voltage source 211. A low potential side power supply terminal of the power supply voltage source 211 is connected to a ground voltage terminal GND. Note that reference symbol “GND” denotes a terminal name as well as a ground voltage. A high potential side power supply terminal of the power supply voltage source 211 is connected to the force terminal 205.

The probe card 212 includes a probe needle 201, a sense line 208, a force line 206, a fuse 202, and a capacitive element 204. The force terminal 205, the sense terminal 207, and the probe needle 201 are connected to one another through a node 203. A signal line connecting the force terminal 205 and the node 203 is referred to as the force line 206. A signal line connecting the sense terminal 207 and the node 203 is referred to as the sense line 208.

The fuse 202 is connected in series between the node 203 and the probe needle 201. That is, one terminal of the fuse 202 is connected to the node 203, and the other terminal of the fuse 202 is connected to the probe needle 201. One terminal of the capacitive element 204 is connected to a signal line which connects the fuse 202 and the probe needle 201. The other terminal of the capacitive element 204 is connected to the ground voltage terminal GND. The capacitive element 204 represents a parasitic capacitance of the probe needle 201, lines, or the like.

Next, the operation of the circuit shown in FIG. 4 will be described. In the semiconductor testing device body 213, the reference voltage 210 is applied to one input terminal of the amplifier 209. The reference voltage 210 can be changed depending on the conditions of semiconductor testing. A feedback signal (described later) is input to the other input terminal of the amplifier 209. In this case, a signal having a current value and a voltage value that correspond to a potential difference between the reference voltage 210 and the voltage of the feedback signal is output from the amplifier 209. The output signal of the amplifier 209 is input to the control terminal of the power supply voltage source 211. The power supply voltage source 211 outputs a voltage corresponding to the output signal of the amplifier 209 to the force terminal 205.

In the probe card 212, the voltage supplied from the semiconductor testing device body 213 to the force terminal 205 is applied to the probe needle 201 through the force line 206 and the fuse 202 in the stated order. Likewise, in the probe card 212, the voltage supplied from the semiconductor testing device body 213 to the force terminal 205 is applied to the sense terminal 207 through the force line 206, the node 203, and the sense line 208 in the stated order. Further, in the semiconductor testing device body 213, the voltage supplied from the probe card 212 to the sense terminal 207 is input to the other input terminal of the amplifier 209 as the feedback signal. At this time, the current value and voltage value of the feedback signal are controlled based on a potential difference between two input signals input to the amplifier 209. That is, the current value and voltage value of the feedback signal are controlled so as not to cause a potential difference between the two input signals input to the amplifier 209. In other words, the power supply voltage source 211 controls the current value and voltage value of the feedback signal so as not to cause a potential difference between the two input signals input to the amplifier 209. This enables the circuit shown in FIG. 4 to supply a stable power supply voltage to the probe needle 201. The probe needle 201 is electrically connected to a semiconductor integrated circuit to be tested.

A description is now given of a case where an overcurrent flows from the semiconductor testing device body 213 to the semiconductor integrated circuit through the probe needle 201. If no countermeasure is taken in this case, there arises a problem that the probe needle 201 is damaged, for example. As a countermeasure against this problem, the circuit shown in FIG. 4 incorporates the fuse 202 which is connected in series between the node 203 and the probe needle 201. Specifically, when the current flowing through the fuse 202 exceeds a predetermined current value, the fuse 202 is fused. Thus, no current flows to the probe needle 201. For example, a configuration is made such that the fuse 202 is fused before the current flowing to the probe needle 201 reaches the current value at which the probe needle 201 is damaged. This prevents the probe needle 201 from being damaged due to an overcurrent, for example.

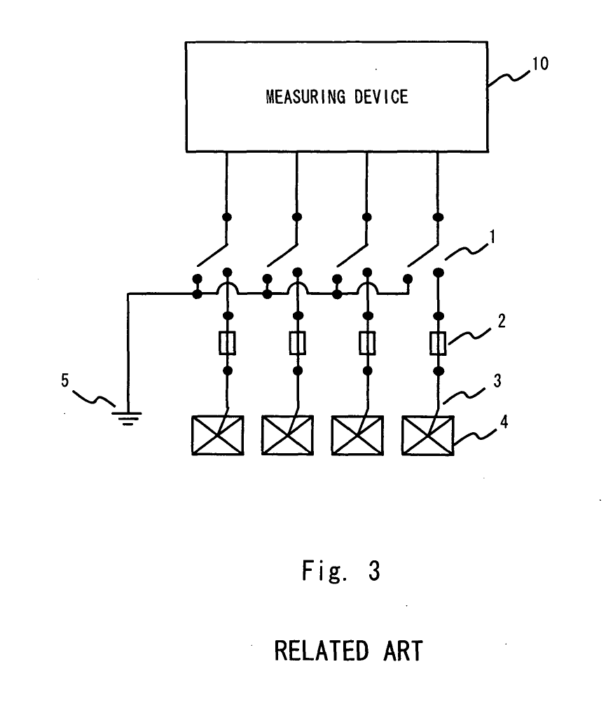

In the circuit shown in FIG. 4, however, the power supply voltage supplied to the probe needle 201 is affected by a voltage drop due to a resistance component of the fuse 202, as in the case of the circuit shown in FIG. 3. Accordingly, it is impossible to supply a power supply voltage with high accuracy to the semiconductor integrated circuit from the semiconductor testing device 200 in the circuit shown in FIG. 4. This may cause deterioration in reliability of product inspection.

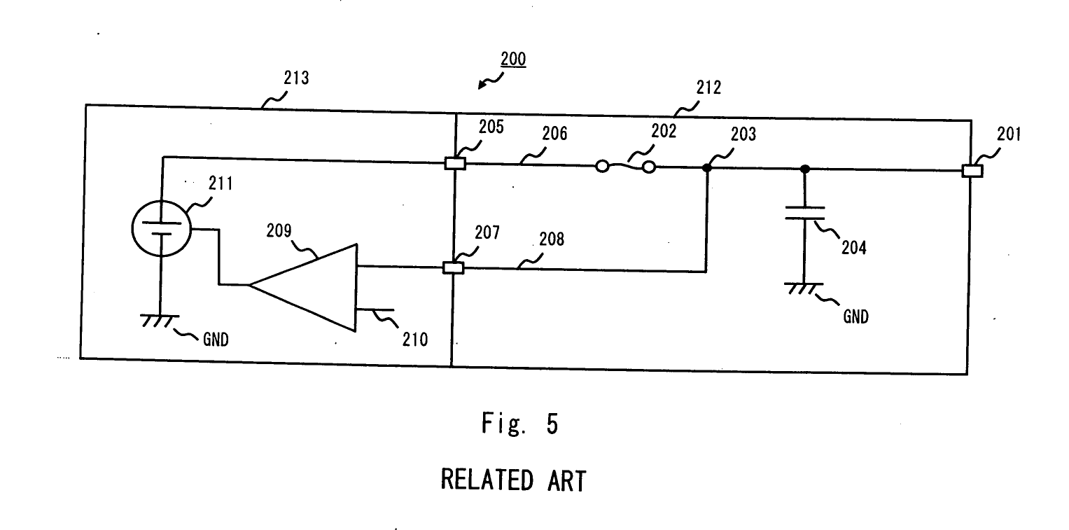

As a countermeasure against the problems inherent in the circuit disclosed in Japanese Unexamined Patent Application Publication No. 2002-124552 and the circuit of the related art shown in FIG. 4, a circuit shown in FIG. 5 is also proposed. The circuit shown in FIG. 5 is different from the circuit shown in FIG. 4 in the connection of the fuse 202. Specifically, the fuse 202 is connected in series between the force terminal 205 and the node 203. That is, one terminal of the fuse 20 is connected to the force terminal 205 and the other terminal thereof is connected to the node 203. The other circuit configuration and operation are similar to those of FIG. 4, so the description thereof is omitted.

In the circuit shown in FIG. 5, the fuse 202 is not interposed between the probe needle 201 and the node 203 having a stable power supply voltage. In this circuit configuration, the power supply voltage supplied to the probe needle 201 is not affected by a voltage drop due to a resistance component of the fuse 202. Therefore, it is possible to supply the power supply voltage with high accuracy to the semiconductor integrated circuit from the semiconductor testing device 200. Additionally, configuration is made such that the fuse 202 is fused before the current flowing to the probe needle 201 reaches the current value at which the probe needle 201 is damaged. This prevents the probe needle 201 from being damaged due to an overcurrent, for example.

However, the semiconductor testing device body 213 may have a circuit configuration in which, for example, a signal line connecting the high potential side power supply terminal of the power supply voltage source 211 and the force terminal 205, and a signal line connecting the sense terminal 207 and the other input terminal of the amplifier 209 are electrically connected to each other through an internal circuit (not shown). In this circuit configuration, when the fuse 202 is fused due to an overcurrent, such a phenomenon that a current flows to the probe needle 201 has been confirmed. Thus, a current flows to the probe needle 201 even when the semiconductor testing device 200 is not in a satisfactory condition for normally checking the semiconductor integrated circuit. Accordingly, there is a possibility of performing product inspection without recognizing that the fuse 202 is fused. This may cause deterioration in reliability of product inspection.

### [First Exemplary Embodiment]

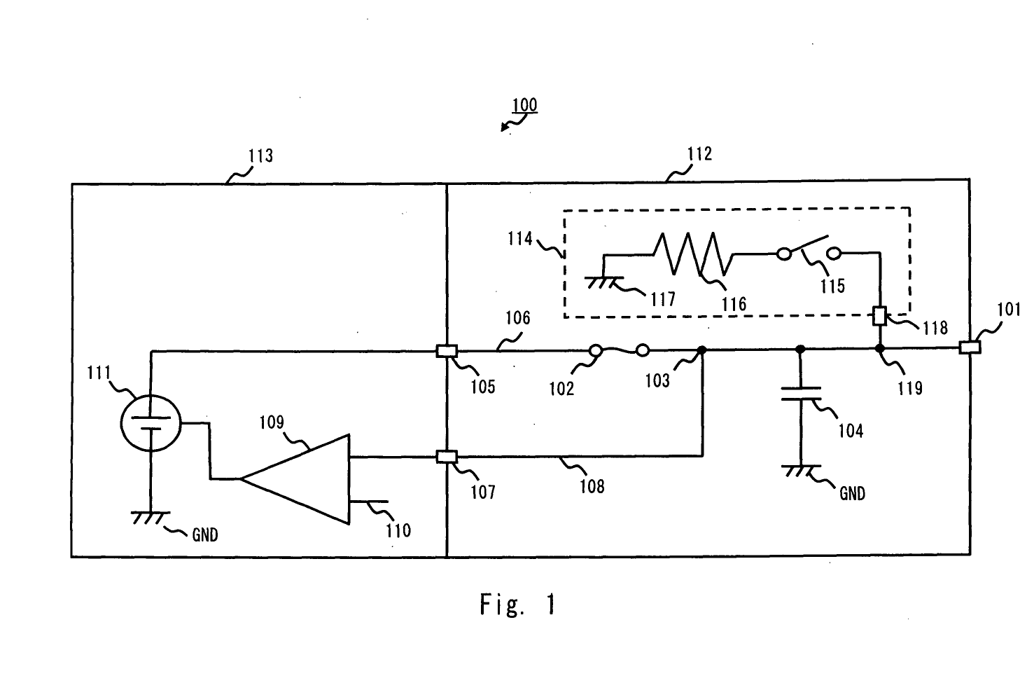

A first exemplary embodiment of the present invention will be described with reference to the drawings. A circuit shown in FIG. 1 is a semiconductor testing device 100 which includes a probe card 112 according to the first exemplary embodiment of the present invention and a semiconductor testing device body 113.

First, the configuration of the circuit shown in FIG. 1 will be described. The semiconductor testing device body 113 includes an amplifier 109 and a power supply voltage source 111, and supplies a power supply voltage for inspection of a semiconductor integrated circuit. Note that FIG. 1 illustrates only a part of the circuit configuration of the semiconductor testing device body 113, for simplification of the explanation. In the semiconductor testing device body 113, one input terminal of the amplifier 109 is connected to a reference voltage terminal 110. For convenience of description, a reference voltage supplied to the reference voltage terminal 110 is referred to as a reference voltage (set voltage) 110. The other input terminal of the amplifier 109 is connected to a sense terminal 107 (third power supply electrode). For convenience of description, it is assumed that the sense terminal 107 is a terminal common to the probe card 112 and the semiconductor testing device body 113. Likewise, it is assumed that a force terminal 105 (first power supply electrode) is a terminal common to the probe card 112 and the semiconductor testing device body 113. An output terminal of the amplifier 109 is connected to a control terminal of the power supply voltage source 111. A low potential side power supply terminal of the power supply voltage source 111 is connected to the ground voltage terminal GND. A high potential side power supply terminal of the power supply voltage source 111 is connected to the force terminal 105. Note that reference symbol “GND” denotes a terminal name as well as a ground voltage.

The probe card 112 includes a probe needle 101, a sense line 108, a force line 106, a fuse 102, a fuse check circuit 114, and a capacitive element 104. The force terminal 105, the sense terminal 107, and the probe needle 101 are connected to one another through a node 103 (second node). A signal line connecting the force terminal 105 and the node 103 is referred to as the force line 106. A signal line connecting the sense terminal 107 and the node 103 is referred to as the sense line 108.

The fuse 102 is connected in series on the force line 106. That is, one terminal of the fuse 102 is connected to the force terminal 105. The other terminal of the fuse 102 is connected to the node 103. One terminal of the capacitive element 104 is connected on a signal line which connects the node 103 and the probe needle 101. The other terminal of the capacitive element 104 is connected to the ground voltage terminal GND. The capacitive element 104 represents a parasitic capacitance of the probe needle 101, lines, or the like. A terminal 118 of the fuse check circuit 114 is connected to a node 119 (first node) on the signal line which connects the node 103 and the probe needle 101.

The fuse check circuit 114 includes a switch 115 and a resistive element 116. The terminal 118 is connected to one terminal of the switch 115. The other terminal of the switch 115 is connected to a low potential side power supply terminal 117 (second power supply electrode) through the resistive element 116. Note that, in an exemplary embodiment of the present invention, a description is given of a case where the ground voltage GND is supplied to the low potential side power supply terminal 117.

Next, the operation of the circuit shown in FIG. 1 will be described. In the semiconductor testing device body 113, the reference voltage 110 is applied to one input terminal of the amplifier 109. The reference voltage 110 can be changed depending on the conditions of semiconductor testing. A feedback signal (described later) is input to the other input terminal of the amplifier 109. In this case, a signal having a current value and a voltage value that correspond to a potential difference between the reference voltage 110 and the voltage of the feedback signal is output from the amplifier 109. The output signal of the amplifier 109 is input to the control terminal of the power supply voltage source 111. The power supply voltage source 111 outputs a voltage corresponding to the output signal of the amplifier 109 to the force terminal 105.

In the probe card 112, the voltage supplied from the semiconductor testing device body 113 to the force terminal 105 is applied to the probe needle 101 through the force line 106 and the fuse 102 in the stated order. Likewise, in the probe card 112, the voltage supplied from the semiconductor testing device body 113 to the force terminal 105 is applied to the sense terminal 107 through the force line 106, the node 103, and the sense line 108 in the stated order. Then, in the semiconductor testing device body 113, the voltage supplied from the probe card 112 to the sense terminal 107 is input to the other input terminal of the amplifier 109 as the feedback signal. At this time, the current value and voltage value of the power supply voltage source 111 are controlled based on a potential difference between two input signals input to the amplifier 109. That is, the current value and voltage value of the feedback signal are controlled so as not to cause a potential difference between the two input signals input to the amplifier 109. In other words, the power supply voltage source 111 controls the current value and voltage value of the feedback signal so as not to cause a potential difference between the two input signals input to the amplifier 109. This enables the circuit shown in FIG. 1 to supply a stable power supply voltage to the probe needle 101. The probe needle 101 is electrically connected to a semiconductor integrated circuit to be tested.

A description is now given of a case where an overcurrent flows from the semiconductor testing device body 113 to the semiconductor integrated circuit through the probe needle 101. If no countermeasure is taken in this case, there arises a problem that the probe needle 101 is damaged, for example. As a countermeasure against this problem, the semiconductor testing device 100 shown in FIG. 1 employs a circuit configuration in which the fuse 102 is connected in series between the force terminal 105 and the node 103. Specifically, when the current flowing through the fuse 102 exceeds a predetermined current value, the fuse 102 is fused. Thus, no current flows to the probe needle 101. For example, a configuration is made such that the fuse 102 is fused before the current flowing to the probe needle 201 reaches the current value at which the probe needle 101 is damaged. This prevents the probe needle 101 from being damaged due to an overcurrent, for example.

Moreover, in the probe card 112 of the semiconductor testing device 100 shown in FIG. 1, the fuse 102 is not interposed between the probe needle 101 and the node 103 having a stable power supply voltage. In this circuit configuration, the power supply voltage supplied to the probe needle 101 is not affected by the voltage drop caused due to the resistance component of the fuse 102. Therefore, it is possible to supply the power supply voltage with high accuracy to the semiconductor integrated circuit from the semiconductor testing device 100. That is, the circuit shown in FIG. 1 is capable of solving the problems inherent in the circuits of the related art shown in FIGS. 3 and 4.

Next, a description is given of a case where the semiconductor testing device body 113 has a circuit configuration in which, for example, a signal line connecting the high potential side power supply terminal of the power supply voltage source 111 and the force terminal 105, and a signal line connecting the sense terminal 107 and the other input terminal of the amplifier 109 are electrically connected to each other through an internal circuit (not shown). In this circuit configuration, when the fuse 102 is fused due to an overcurrent, such a phenomenon that a current flows to the probe needle 101 has been confirmed. Thus, a current flows to the probe needle 101 even when the semiconductor testing device 100 is not in a satisfactory condition for normally checking the semiconductor integrated circuit. Accordingly, there is a possibility of performing product inspection without recognizing that the fuse 102 is fused. This may cause deterioration in reliability of product inspection.

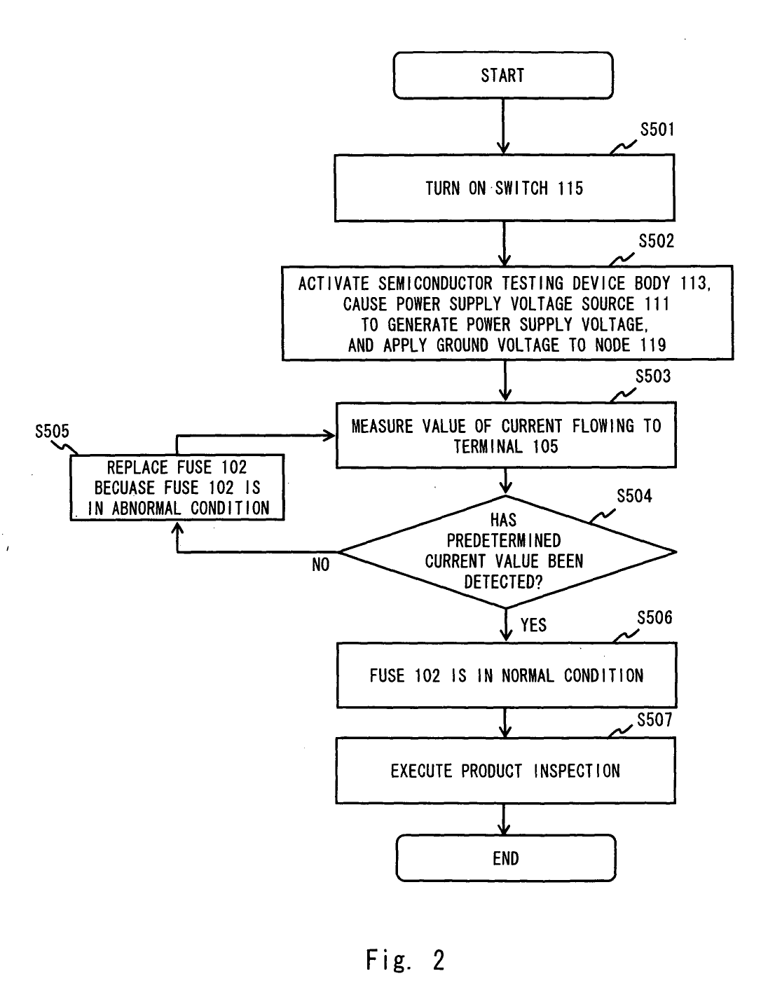

As a countermeasure against the problem, the semiconductor testing device 100 shown in FIG. 1 employs a circuit configuration in which the probe card 112 includes the fuse check circuit 114. This makes it possible to check a connection state of the fuse 102 (check if the fuse 102 is not fused) prior to the product inspection. A specific fuse checking method will be described with reference to FIG. 2. First, the switch 115 provided in the fuse check circuit 114 is turned on (S501). Next, the semiconductor testing device body 113 is activated to cause the power supply voltage source 111 to generate a power supply voltage. At this time, the ground voltage is applied from the low potential side power supply terminal 117 to the node 119 (S502). After a potential difference is generated between the both terminals of the fuse 102 in this manner, the value of the current flowing to the force terminal 105 is measured (S503). When the fuse 102 is not fused, a current corresponding to the power supply voltage generated by the power supply voltage source 111 flows to the force terminal 105 (YES in S504). As a result, it can be determined that the fuse 102 is in a normal condition (not fused) (S506). In this manner, when it is confirmed that the fuse 102 is in a normal condition, a subsequent product inspection is carried out (S507). On the other hand, when it is determined that the fuse 102 is fused, no current flows to the force terminal 105 (NO in S504). Accordingly, it can be determined that the fuse 102 is in an abnormal condition (fused). Note that, in this exemplary embodiment, since the node 119 is applied with the ground voltage, no current flows to the probe needle 101 as well. In this case, the fuse 102 is replaced (S505), and fuse checking is carried out again (S503).

In this way, the probe card 112 according to an exemplary embodiment of the present invention includes the fuse check circuit 114 so as to generate a potential difference between the both terminals of the fuse 102 during fuse checking, thereby enabling checking of the connection state of the fuse 102 prior to the product inspection. This prevents the product inspection from being performed without recognizing that the fuse 102 is fused. As a result, the reliability of product inspection can be improved. In other words, the circuit shown in FIG. 1 is capable of solving the problems inherent in the circuit of the related art shown in FIG. 5.

Note that the probe card 112 and the semiconductor testing device 100 including the same are not limited to those of the above-mentioned exemplary embodiment, and various modifications can be made without departing from the scope of the present invention. For example, though the above-mentioned exemplary embodiment describes the case where the ground voltage is supplied to the low potential side power supply terminal 117, the present invention is not limited thereto. Any power supply voltage may be supplied to the low potential side power supply terminal 117, as long as the power supply voltage causes a potential difference between the power supply voltages generated by the power supply voltage source 111.

Furthermore, a socket-type configuration may also be employed at a position where the fuse 102 is inserted. This facilitates replacement of the fuse 102 in which a defect is detected during fuse checking.

This fuse checking may be preferably performed in a state where the probe needle 101 is unconnected to a semiconductor device. If it is impossible due to limitations of the functions or the like of the semiconductor device, it is necessary to set a decision time and a decision value for fuse checking and a value of the resistive element 116, in view of an overcurrent or static current flowing through a load connected to the probe needle 101.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A probe card comprising:
a first power supply electrode that is supplied with a first power supply voltage;
a probe needle that supplies a voltage corresponding to the first power supply voltage to a semiconductor integrated circuit to be tested;
a first signal line that connects the first power supply electrode and the probe needle;
a fuse that is connected in series on the first signal line; and
a fuse check circuit that supplies a voltage different from the first power supply voltage, to a first node which is located on the first signal line between the probe needle and one end of the fuse.

2. The probe card according to claim 1, wherein the fuse check circuit comprises a switch element that is connected in series between a second power supply electrode that is supplied with a second power supply voltage different from the first power supply voltage, and the first node through a resistor.

3. The probe card according to claim 2, wherein the switch element is controlled to be turned on and off between a mode for testing the semiconductor integrated circuit and a mode for checking a connection state of the fuse.

4. The probe card according to claim 3, wherein the fuse check circuit supplies a voltage different from the first power supply voltage, to the first node by turning on the switch element in the mode for checking the connection state of the fuse.

5. The probe card according to claim 1, further comprising:
a third power supply electrode that supplies a third power supply voltage; and
a second signal line that connects the third power supply electrode and a second node located on the first signal line,
wherein the first power supply voltage supplied to the first signal line is controlled based on a potential difference between a set voltage and a voltage on the second signal line.

6. The probe card according to claim 5, wherein the second node is located on the first signal line between the probe needle and one end of the fuse.

7. The probe card according to claims 1, wherein the fuse is fused before a current flowing to the probe needle reaches a current value at which the probe needle is damaged.

8. A semiconductor testing device comprising a probe card claimed in claim 1.

9. A fuse checking method for a probe card, the probe card comprising: a first power supply electrode that is supplied with a first power supply voltage; a probe needle that supplies a voltage corresponding to the first power supply voltage to a semiconductor integrated circuit to be tested; a first signal line that connects the first power supply electrode and the probe needle; a fuse that is connected in series on the first signal line; and a fuse check circuit that supplies a voltage different from the first power supply voltage, to a first node which is located on the first signal line between the probe needle and one end of the fuse, the fuse checking method comprising:
applying the first power supply voltage from the first power supply electrode;
supplying a voltage different from the first power supply voltage, to the first node by turning on a switch element provided in the fuse check circuit; and
detecting a connected state of the fuse when a current corresponding to a potential difference between both terminals of the fuse flows to the first power supply electrode, and detecting a fused state of the fuse when the current corresponding to the potential difference between the both terminals of the fuse doesn't flow to the first power supply electrode.
